(19) United States
(12) Patent Application Publication
(10) Pub. No.: US 2015/0084635 A1
(43) Pub. Date: Mar. 26, 2015

(54) MAGNETIC RESONANCE IMAGING APPARATUS

(71) Applicant: Kabushiki Kaisha Toshiba, Minato-ku (JP)

(72) Inventors: Tamio KAWAGUCHI, Kawasaki (JP); Hiroyuki Kayano, Fujisawa (JP); Noritsugu Shiokawa, Yokohama (JP); Kohei Nakayama, Kawasaki (JP); Mutsuki Yamazaki, Yokohama (JP)

(73) Assignee: Kabushiki Kaisha Toshiba, Minato-ku (JP)

(21) Appl. No.: 14/483,772

(22) Filed: Sep. 11, 2014

(30) Foreign Application Priority Data
Sep. 25, 2013 (JP) 2013-197851
Aug. 8, 2014 (JP) 2014-162767

(51) Int. Cl. G01R 33/38; G01R 33/3815; G01R 33/385; G01R 33/383

(52) U.S. Cl. CPC G01R 33/3804; G01R 33/383; G01R 33/3815; G01R 33/385
USPC 324/322

(57) ABSTRACT

A magnetic resonance imaging apparatus of an embodiment includes a housing, a static magnetic field source having a superconducting coil or a permanent magnet inside the housing, and a superconducting array antenna inside the housing.

### CROSS-REFERENCE TO RELATED APPLICATION

This application is based upon and claims the benefit of priority from Japanese Patent Applications No. 2013-197851, filed on Sep. 25, 2013 and No. 2014-162767, filed on Aug. 8, 2014; the entire contents of which are incorporated herein by reference.

### FIELD

Embodiments described herein relate to a magnetic resonance imaging apparatus.

### BACKGROUND

A magnetic resonance imaging (MRI) apparatus is an apparatus configured to image an inside of a subject by utilizing a magnetic resonance phenomenon. This MRI apparatus includes various devices required for imaging the inside of the subject, such as an external magnet configured to generate a static magnetic field in an imaging area, a gradient magnetic field coil configured to apply a gradient magnetic field to the subject placed in the static magnetic field, and a high frequency coil configured to apply a high frequency pulse to the subject. A superconducting magnet using a superconducting coil is used for the external magnet, and a strong static magnetic field can be generated.

In the MRI, a coil (an antenna) configured to receive a nuclear magnetic resonance phenomenon is disposed on a surface of the subject. The coil for reception to be disposed on the surface of the subject corresponds to an imaging site, and the coil corresponding to the imaging site is needed. Further, the coil for reception to be disposed on the surface of the subject applies oppressive feeling to the subject.

### BRIEF DESCRIPTION OF THE DRAWINGS

FIG. 1 is a configuration conceptual diagram of a magnetic resonance imaging apparatus of an embodiment;

FIG. 2 is a conceptual diagram of a receiving antenna of the embodiment;

FIG. 3 is a conceptual diagram of a magnetic resonance imaging apparatus of the embodiment;

FIG. 4 is a conceptual diagram of a magnetic resonance imaging apparatus of the embodiment;

FIG. 5 is a conceptual diagram of a magnetic resonance imaging apparatus of an embodiment;

FIG. 6 is a conceptual diagram of a magnetic resonance imaging apparatus of the embodiment;

FIG. 7 is a configuration conceptual diagram of a magnetic resonance imaging apparatus of an embodiment;

FIG. 8 is a conceptual diagram of a magnetic resonance imaging apparatus of the embodiment; and

FIG. 9 is a conceptual diagram of a magnetic resonance imaging apparatus of an embodiment.

### DETAILED DESCRIPTION

A magnetic resonance imaging apparatus of an embodiment includes a housing, a static magnetic field source having a superconducting coil or a permanent magnet inside the housing, and a superconducting array antenna inside the housing.

### First Embodiment

A magnetic resonance imaging apparatus of a first embodiment has a housing and a superconducting antenna inside the housing as a receiving antenna. FIG. 1 illustrates a configuration conceptual diagram of the magnetic resonance imaging apparatus of the embodiment. A magnetic resonance imaging apparatus 100 in FIG. 1 has a static magnetic field source 101, a gradient magnetic field coil 102, a transmission coil 103, a receiving antenna 104, a cooling device 106, a receiving unit 107, a transmission unit 108, a gradient magnetic field power source 109, and a controller 110. A top plate 105 is disposed in an imaging range. It should be noted that a subject of the magnetic resonance imaging apparatus includes animals including human beings, chemical substances, or the like.

The static magnetic field source 101, the gradient magnetic field coil 102, the transmission coil 103, and the receiving antenna 104 are provided in the housing of the magnetic resonance imaging apparatus.

The magnetic resonance imaging of the embodiment includes nuclear magnetic resonance (NMR), the MRI, and electron spin resonance (ESR). For example, the MRI includes special imaging, such as magnetic resonance angiography (MRA) or magnetic resonance spectroscopy (MRS).

The static magnetic field source 101 is an external magnet configured to generate a static magnetic field in an imaging area, in which a subject is placed. The external magnet is a magnet of a horizontal magnetic field type. For example, the static magnetic field source 101 has a vacuum chamber, a refrigerant chamber, and a superconducting coil. A power source (not illustrated) for causing a current to flow to the superconducting coil is connected with the static magnetic field source 101. The superconducting coil is cooled by a cooling refrigerant (freezing mixture) including liquid helium, liquid nitrogen, or the like. Here, in order to keep an object to be cooled at a low temperature, the object to be cooled is thermally insulated by vacuum insulation using the vacuum chamber. The vacuum chamber is formed in a substantially cylindrical shape, and an inside of a cylindrical wall is kept in a vacuum state. A space formed inside this vacuum chamber becomes the imaging area, in which the subject is placed. A refrigerant chamber (first refrigerant chamber) is formed in a substantially cylindrical shape and is accommodated within the cylindrical wall of the vacuum chamber. It should be noted that, as a general example, the refrigerant chamber contains liquid helium within the cylindrical wall as the refrigerant to keep an inside of the chamber in a sufficiently low temperature state. The superconducting coil is disposed within the cylindrical wall of the refrigerant chamber and is immersed in the liquid helium. This superconducting coil generates the static magnetic field in the imaging area provided inside the vacuum chamber. It is preferable that at least a part of the vacuum chamber be covered with a refrigerant chamber (second refrigerant chamber) containing a cooling refrigerant including liquid helium, liquid nitrogen, or the like and that heat be relieved from the outside. Moreover, a correction magnet for making a magnetic field uniform may be further provided. The cooling device 106 is, for example, a device configured to liquefy a vaporized cooling refrigerant, and it is preferable that the device 106 be provided in the magnetic resonance imaging apparatus. It is preferable that, even during a time when the magnetic resonance imaging apparatus is not operated, this cooling device 106 be continuously operated regularly in such a manner that the static magnetic field source 101 is always held in a superconducting state.

The gradient magnetic field coil 102 is formed in a substantially cylindrical shape and disposed inside the static magnetic field source 101 within the housing. The gradient magnetic field coil 102 controls an imaging direction. The gradient magnetic field coil 102 in an x axis direction, a y axis direction, and a z axis direction is disposed. This gradient magnetic field coil 102 generates a gradient magnetic field in the x axis direction, the y axis direction, and the z axis direction set in the imaging area according to the corkscrew rule by a current supplied from the gradient magnetic field power source 109. A pulse current is repeatedly supplied to this gradient magnetic field coil 102 during execution of the imaging.

The transmission coil 103 is disposed within the housing. Specifically, the transmission coil 103 is disposed inside the gradient magnetic field coil 102 within the housing. This transmission coil 103 irradiates the subject placed in the imaging area with a high frequency pulse transmitted from the transmission unit 108. The transmission coil 103 generates a rotating magnetic field so as to be rotated within a surface vertical to the static magnetic field. In a case where a nuclear magnetic resonance phenomenon is utilized, a nucleus can be inverted from a ground state to an excited state or from the excited state to the ground state by the high frequency pulse. A frequency of the high frequency pulse is a precession frequency of the nucleus. Similarly, in a case where electron spin resonance is utilized, a precession frequency of an electron is utilized. The subject may be irradiated with the high frequency pulse by using an antenna having a configuration similar to that of the receiving antenna 104.

The receiving antenna 104 is disposed within the housing. Specifically, the receiving antenna 104 is disposed inside the gradient magnetic field coil 102 inside the static magnetic field source 101. The receiving antenna 104 receives an electromagnetic wave generated from the subject by the pulse irradiated from the transmission coil 103. A received signal is transmitted to the receiving unit 107 through optical wiring or conductive wiring. In the embodiment, instead of using an external receiving antenna optimized for an imaging site of the subject, the receiving antenna 104 in a form built in the housing is used. The receiving antenna 104 may have one row or plural rows as in FIG. 1. The plural rows of receiving antennas 104 are preferable from a viewpoint of shortening an imaging time and obtaining an imaged image with high resolution. It is also preferable that efficiency of image processing be improved by increasing the number of antennas. With an increase in the number of antennas, directivity of the antenna can be high. Due to the high directivity, a direction of a radio wave received by one antenna is narrower, and reception sensitivity of the antenna is improved. Since the number of antennas is increased, it is preferable that the signal received by the antenna be sent to the controller 110 or an external device through the optical wiring. Due to the high sensitivity of the receiving antenna, it is preferable that a slice thickness be thinned and that the slice can be arranged in many rows.

It should be noted that, other than the above-described method, there is a method in which the receiving antenna 104 can have a function of the transmission coil. It is possible to have a configuration in which an antenna is shared during transmission and reception and which has an antenna, a transmission/reception circuit, and a transmission/reception switching unit. Regarding the receiving antenna 104, a bandpass filter or a low noise signal amplifier configured to process the signal received by the receiving antenna 104 may be disposed within the housing, such as within the receiving antenna 104. Since a superconducting filter can be used for the bandpass filter, the bandpass filter can be turned into a superconducting state by cooling the antenna or the superconducting magnet. The low noise signal amplifier can amplify a signal with lower noise under a low temperature environment. In this case, the transmission coil 103 is omitted.

Regarding the external receiving antenna, an antenna corresponding to the imaging site of the subject to efficiently receive a weak electromagnetic wave from the subject is disposed in close contact with the subject or in a vicinity of a surface of the subject. When this antenna is disposed within the housing of the magnetic resonance imaging apparatus, a distance between the receiving antenna and the subject is too far, and the measurable electromagnetic wave cannot be received.

In the embodiment, it is preferable that the superconducting antenna be used for the receiving antenna 104. It is more preferable that a superconducting array antenna obtained by laminating the superconducting antennas be used as the receiving antenna 104. Even when an antenna pattern of the superconducting array antenna is minute, loss thereof is small and the antenna can be micronized. Since the loss is small, gain of the antenna is high. Further, the gain and directivity of the antenna is improved by the lamination. A shape of the antenna pattern of the superconducting antenna includes a monopole type, a dipole type, a crank type, a spiral type, such as a rectangle, a circle, and an ellipse, an L-type, an inverted-F type, and the like. Further, an antenna constituted with a CPW type having ground and a signal line on the same surface and with a length of integral multiple of a quarter wavelength, or a slot type antenna where a slot is provided in a part of ground can be included. In order to correspond to various imaging methods, it is more preferable that the receiving antenna 104 be a phased array antenna capable of performing beam scanning.

It is preferable that the superconducting array antenna of the embodiment have an array antenna obtained by laminating the antenna formed of a superconducting material and a planar antenna having a ground pattern, on a dielectric substrate having low loss in a shortwave band to a millimeter wave band.

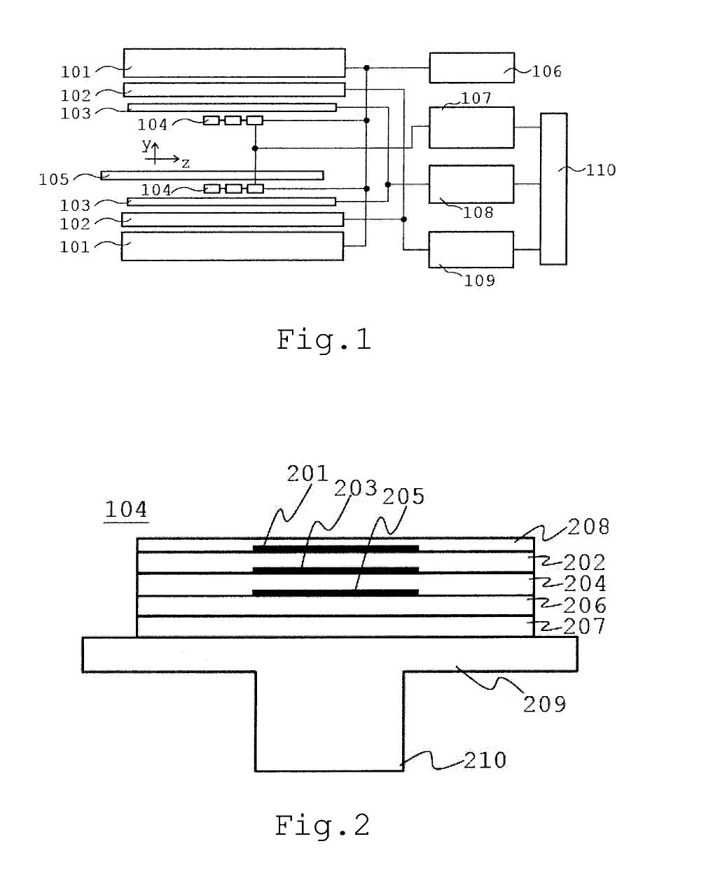

FIG. 2 illustrates a conceptual diagram of the receiving antenna 104 of the embodiment. The receiving antenna 104 has a first superconducting antenna layer 201, a first substrate 202, a second superconducting antenna layer 203, a second substrate 204, a third superconducting antenna layer 205, a third substrate 206, a superconducting ground layer 207, an infrared reflective film 208, a cold head 209, and a cooling medium 210.

As illustrated in the conceptual diagram of FIG. 2, the array antenna (the receiving antenna 104) of the embodiment is formed by laminating the first superconducting antenna layer 201, the first substrate 202, the second superconducting antenna layer 203, the second substrate 204, the third superconducting antenna layer 205, the third substrate 206, and the superconducting ground layer 207 in this order. A feeding path (not illustrated) is provided on the antenna layer. The feeding path is connected with the receiving unit 107 (not illustrated in FIG. 2). Further, each superconducting antenna layer connects the feeding path and the ground layer. The superconducting antenna layer has an antenna pattern, in which an oxide superconductor thin film containing one or more elements, such as Y, Ba, Cu, La, Ta, Bi, Sr, Ca, and Pb, has been processed into a desired shape, the feeding path, and a ground pattern.

The infrared reflective film 208 is a film configured to prevent infrared, which heats the antenna, from being incident on the antenna. The infrared reflective film 208 is provided on a surface of the antenna (the first superconducting antenna layer 201) and prevents incidence of the infrared, which heats the superconducting antenna layer. The infrared reflective film 208 is, for example, a multilayer film formed of a metal oxide. The infrared reflective film 208 can be omitted in case of no infrared source or the like.

The cold head 209 is a member having high thermal conductivity and configured to hold and cool the array antenna. The cold head 209 is cooled by thermally connecting with the cooling medium 210. A cooling temperature is different depending on a superconducting oxide thin film of the array antenna and is, for example, 77 K or lower.

The cooling medium 210 is a member configured to cool the cold head 209, which cools the array antenna. The cooling medium 210 may be cooled by a cooler for an array antenna, or may be made common with a cooling member, such as the cooling refrigerant used for cooling the superconducting coil of the static magnetic field source 101 and including liquid helium or liquid nitrogen.

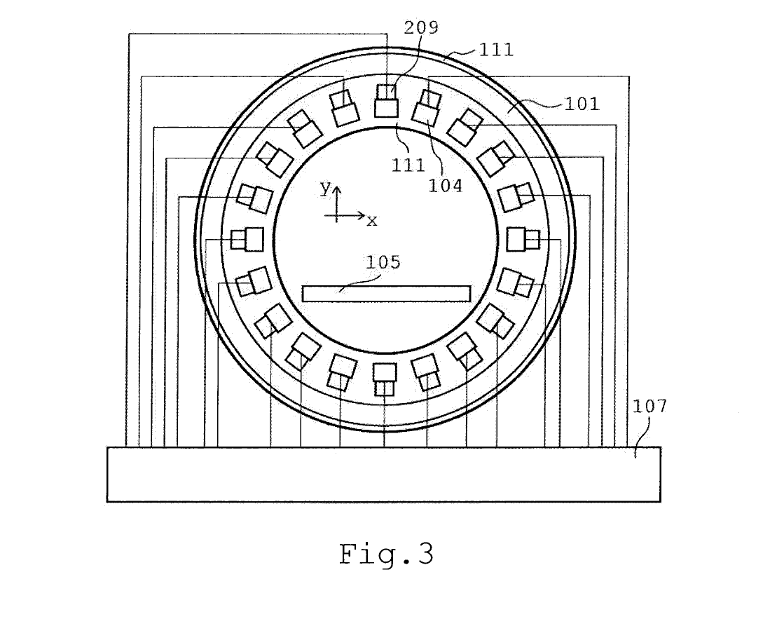

Next, FIG. 3 illustrates a conceptual cross-sectional diagram of the magnetic resonance imaging apparatus of the embodiment having the receiving antenna 104 inside the housing. The magnetic resonance imaging apparatus in the conceptual diagram of FIG. 3 has, within a housing 111, the static magnetic field source 101, the receiving antenna 104, the cold head 209, and the receiving unit 107. The top plate 105, on which the subject is placed, is disposed in the imaging area during the imaging. Illustration of the gradient magnetic field coil 102, the transmission coil 103, and the like is omitted. The receiving antenna 104 is disposed inside the static magnetic field source 101. An output (not illustrated) of each receiving antenna 104 and the receiver 107 are connected through the wiring, and the signal received by the receiving antenna 104 is transmitted to the receiver 107 through the wiring. In FIG. 3, the 20 receiving antennas 104 are formed. The receiver 107 and the like may be provided inside the housing 111. By using superconductivity, the receiving antenna 104 is microminiaturized, and many antennas can be disposed within the housing 111. Since the number of receiving antennas 104 which can be disposed in the housing 111 is changed by a receiving frequency, the number of antennas illustrated is one example. In case of the magnetic resonance imaging apparatus, in which a diameter of a hollow opening part (subject region) of the housing 111 is 70 cm and external magnetic field intensity is 1.5 T, for example, the 50 receiving antennas 104 are disposed inside the superconducting coil, and tens of rows thereof can be further disposed. Since imaging can be performed by using the great many receiving antennas 104, it is possible to perform imaging with high resolution, which cannot be realized by the external receiving antenna. In the conventional receiving coil, it is difficult to reduce a size thereof due to the large loss, and it is necessary to bring nearly in contact with the subject to increase the sensitivity. Accordingly, the antennas cannot be placed within the housing inside the superconducting coil due to the limitation on the size and characteristics. Alternatively, if they are placed, the number of antennas is limited to about ten. In the embodiment, the receiving antenna 104 itself is small, and sensitivity of the plurality of small superconducting antennas is improved by arraying. Accordingly, characteristics can be obtained even when the antennas are separated from the subject, and the tens of antennas can be disposed inside the superconducting coil because of the small size. Therefore, compared with the conventional receiving coil, measurement can be performed with high sensitivity.

A center part C of the housing 111 is a region X of a central part of the housing. It is preferable that the receiving antenna 104 be disposed in such a manner that directivity is oriented in a center part C₁ (e.g., (x₁, y₁, z₁)). In a case where plural rows of the receiving antennas 104 are provided, it is preferable that the receiving antenna 104 of each row be disposed in such a manner that the directivity is oriented in a center part Ca (e.g., (x₁, y₁, zₐ)) deviated only in a z-axis direction. The receiving antennas 104 are oriented in a direction of the center part C. The receiving antennas 104 are disposed on a (virtual) circumference so as to draw a circumference on an inner circumferential side of the static magnetic field source 101. It is preferable that the receiving antennas 104 are disposed at equal distances from the center part from a viewpoint of reducing characteristic differences among the respective antennas. It is preferable that a plurality of the receiving antennas 104 be disposed at equal intervals. It is preferable that the receiving antennas 104 be disposed so as to be surrounded by the static magnetic field source 101.

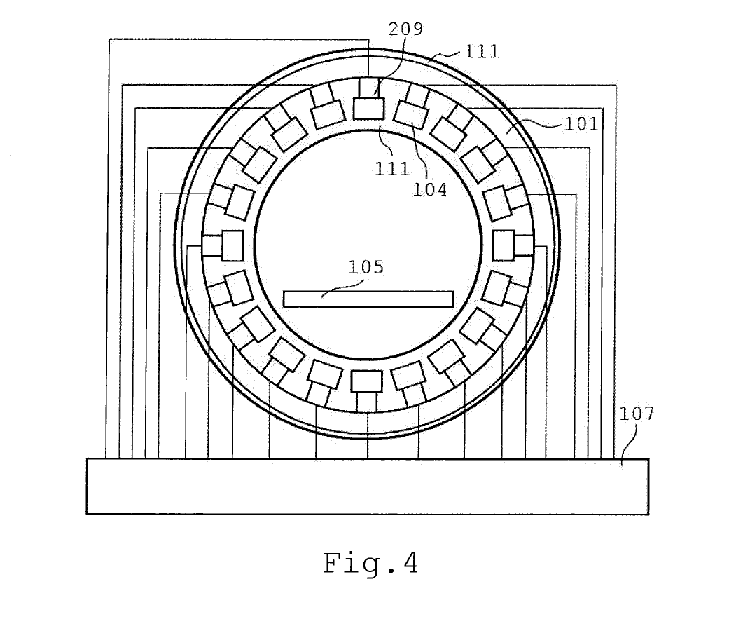

Next, FIG. 4 illustrates a conceptual cross-sectional diagram of a magnetic resonance imaging apparatus of the embodiment having the receiving antenna 104 inside the housing. The superconducting coil in the static magnetic field source 101 and the superconducting antenna 104 are cooled by a common cooling refrigerant. A difference between the magnetic resonance imaging apparatuses in the conceptual diagrams of FIGS. 3 and 4 is that the cold head 209 connects a low temperature area of the static magnetic field source 101 and the receiving antenna 104. Since it is necessary to cool the superconducting coil of the static magnetic field source 101 to be in a superconducting state, the superconducting antenna 104 can be also cooled. For the apparatus in this form, it is not necessary to separately provide a cooler for cooling the receiving antenna 104, and the apparatus can be configured efficiently.

A superconducting material is used for the receiving antenna 104, which is cooled until the superconducting material is turned into a superconducting state. It is preferable that a circuit formed of the superconducting material and configured to process a signal received by the receiving antenna 104 be provided within the receiving antenna 104. A superconducting filter is used as the circuit formed of the superconducting material. An electromagnetic wave received by the superconducting antenna includes noise other than a target frequency, and it is preferable that this be removed before amplifying a signal. The superconducting filter functions as a bandpass filter with low loss.

Besides the circuit formed of the superconducting material, it is preferable that the receiving antenna 104 have a circuit device preferably operated at a low temperature. A low noise amplifier configured to amplify a received signal is used as this circuit device. The signal can be amplified under a lower temperature environment where the receiving antenna 104 is operated and under a condition of no or very little thermal fluctuation. Besides the low noise amplifier, an amplitude limiter of the received signal for protecting the circuit may be provided within the receiving antenna 104.

Further, a phased array antenna may be used for the receiving antenna 104 so as to arbitrarily change a direction where the receiving antenna 104 is oriented. In this case, a phase shifter is provided within or outside the receiving antenna 104.

The top plate 105 is supported by a bed (not illustrated). Further, the subject is placed on the top plate 105 during the imaging, and the top plate 105 is moved into the imaging area with the subject.

The receiving unit 107 detects a magnetic resonance signal received by the receiving antenna 104, and generates raw data by performing, as needed, any one or more of analog processing, digitization processing (conversion of an analog signal to a digital signal), and digital processing to the detected magnetic resonance signal. Then, the receiving unit 107 transmits the generated raw data to the controller 110.

The transmission unit 108 transmits a high frequency pulse to the transmission coil 103 based on an instruction from the controller 110. This transmission unit 108 has a high frequency power source for generating a high frequency pulse to be transmitted to the transmission coil 103.

The gradient magnetic field power source 109 supplies a current to the gradient magnetic field coil 102 based on an instruction from the controller 110.

The controller 110 images the subject by respectively driving the gradient magnetic field power source 109, the transmission unit 108, and the receiving unit 107. Then, when the raw data is transmitted from the receiving unit 107 as a result of the imaging, the controller 110 calculates the raw data and outputs the data as image data or transmits the data to an external device or internal device for processing or storing data.

When the subject is examined, it is possible that a partial scan is first performed to position the subject, position information is obtained by analyzing the data, and then the data is acquired by optimizing imaging conditions. Alternatively, the imaging may be performed without performing pre-scan. The magnetic resonance imaging apparatus can be used as a diagnostic apparatus during surgery. Since it is not necessary to attach coils to a patient at this time, the apparatus can be used as an apparatus for performing a prompt and hygienic diagnosis in the same way as CT (computed tomography).

### Second Embodiment

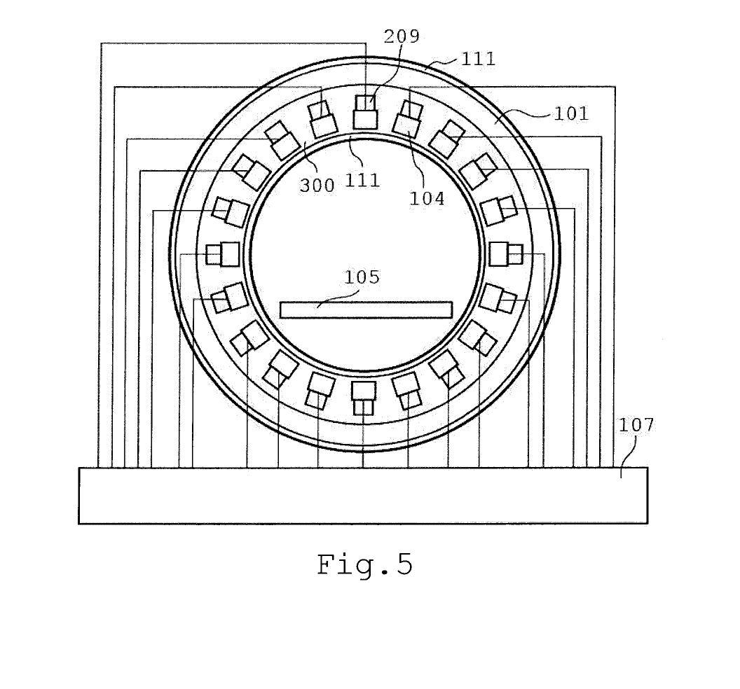

FIG. 5 illustrates a conceptual cross-sectional diagram of a magnetic resonance imaging apparatus of an embodiment having a receiving antenna 104 inside a housing. The magnetic resonance imaging apparatus in the conceptual diagram of FIG. 5 has, within a housing 111, a static magnetic field source 101, a receiving antenna 104, a receiving unit 107, a cold head 209, and a second refrigerant chamber 300. A top plate 105, on which a subject is placed, is disposed in an imaging area during imaging. Other than the second refrigerant chamber 300, a configuration of the magnetic resonance imaging apparatus in FIG. 5 is in common with that of the magnetic resonance imaging apparatus in FIG. 3. In the second embodiment, description of things in common with the aforementioned embodiment is omitted.

In the second embodiment, cooling of the receiving antenna 104 in the magnetic resonance imaging apparatus in an embodied form will be described. A superconducting coil of the static magnetic field source 101 is cooled by a cooling refrigerant, such as liquid helium. In order to prevent an influence of heat on the liquid helium, it is preferable that at least a part or a whole of a vacuum chamber having a first refrigerant chamber containing the liquid helium be covered with the second refrigerant chamber 300 containing a cooling refrigerant (freezing mixture) including liquid helium or liquid nitrogen. In the present embodiment, the second refrigerant chamber 300 containing this cooling refrigerant is effectively utilized thermally and spatially. At least a superconducting array antenna of the receiving antenna 104 is cooled by this cooling refrigerant (mainly liquid nitrogen from the viewpoint of cost) and is cooled to a superconducting state. Therefore, it is preferable that a superconducting member used for the receiving antenna 104 be a so-called high temperature superconductor. Since the receiving antenna 104 is disposed within the refrigerant chamber for liquid nitrogen also used in the magnetic resonance imaging apparatus in the form requiring a conventional external receiving antenna, there is no or little reduction in the imaging area (an opening diameter).

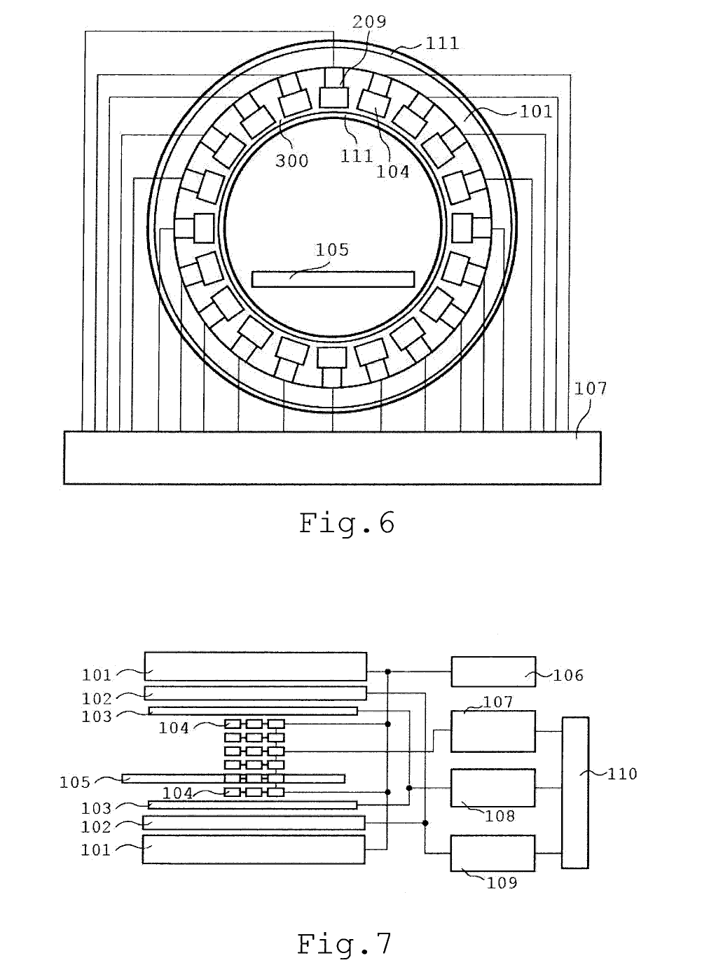

FIG. 6 illustrates a magnetic resonance imaging apparatus in a form where the second refrigerant chamber 300 is provided in the magnetic resonance imaging apparatus of the first embodiment illustrated in FIG. 4. The second refrigerant chamber 300 and the cold head 209 are connected with each other. In the present embodiment as well, effects similar to those of the above-described embodiment are obtained by the second refrigerant chamber 300.

### Third Embodiment

A third embodiment relates to a magnetic resonance imaging apparatus of a vertical magnetic field type. FIG. 7 illustrates a configuration conceptual diagram of the magnetic resonance imaging apparatus of the third embodiment. The magnetic resonance imaging apparatus in FIG. 7 has a static magnetic field source 101, a gradient magnetic field coil 102, a transmission coil 103, a receiving antenna 104, a cooling device 106, a receiving unit 107, a transmission unit 108, a gradient magnetic field power source 109, and a controller 110 for applying a vertical magnetic field to a subject. A top plate 105 is disposed in an imaging range. In the third embodiment, description of things in common with the aforementioned embodiments is omitted.

The static magnetic field source 101 may be a magnet for a superconducting coil or a permanent magnet. In a case where the static magnetic field source 101 is the permanent magnet, the cooling device 106 liquefies vaporized cooling refrigerant configured to cool the receiving antenna 104. In this case, it is preferable that the cooling refrigerant include liquid nitrogen or liquid helium.

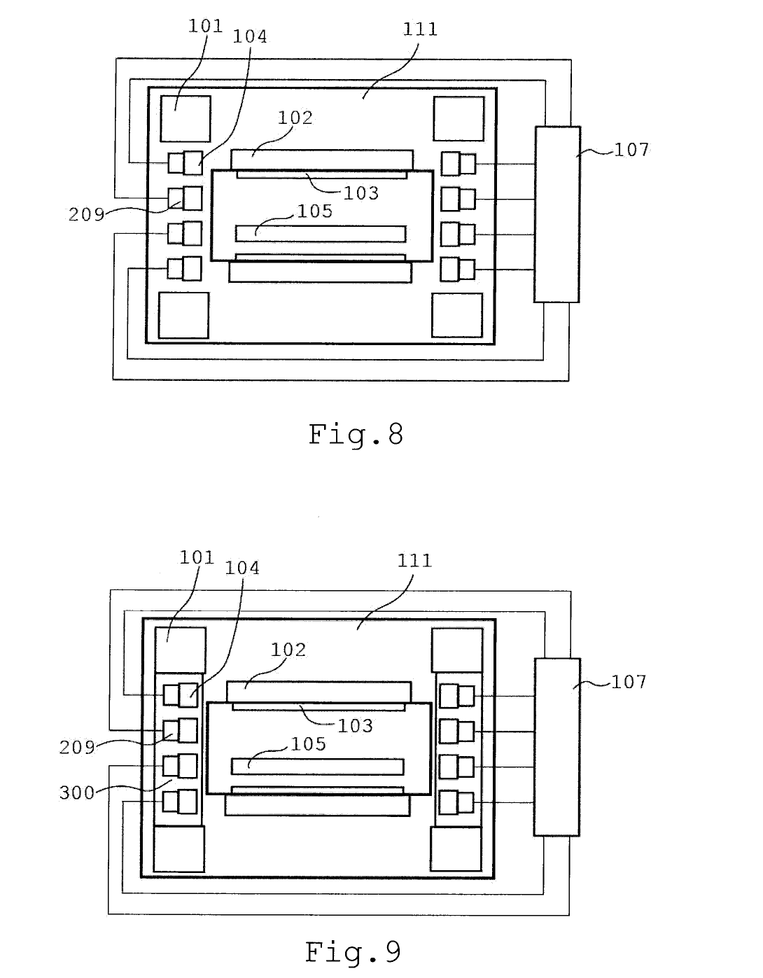

FIG. 8 is a conceptual cross-sectional diagram of a magnetic resonance imaging apparatus of the third embodiment as viewed in a different direction. In FIG. 8, illustration of several components, such as the cooling device 106, is omitted. The magnetic resonance imaging apparatus in FIG. 8 has the static magnetic field source 101, the gradient magnetic field coil 102, the transmission coil 103, the receiving antenna 104, the receiving unit 107, the housing 111, and the cold head 209. The top plate 105, on which the subject is placed, is disposed in an imaging area during imaging.

In the magnetic resonance imaging apparatus in FIG. 8, the receiving antennas 104 cooled within a refrigerant chamber 300, which contains the cooling refrigerant including liquid helium or liquid nitrogen, are disposed between the static magnetic field sources 101. The receiving antennas 104 are disposed in an area of supports within the housing 111. The magnetic resonance imaging apparatus of the vertical magnetic field is called an open type, and it is preferable that an area other than the supports be opened.

In the third embodiment, because of the vertical magnetic field type, the static magnetic field source 101 or the like is separated into upper and lower parts of the imaging area. A configuration including the static magnetic field source 101 separated into the upper and lower parts are supported by the supports of the housing 111. The receiving antennas 104 may be a form disposed at one support. It is preferable that the receiving antennas 104 of the embodiment be disposed within the support so as to include directivity in the imaging area direction. A form of two supports is illustrated. However, the number of supports and a ratio of the support, at which the receiving antenna 104 is disposed, can be changed according to a design of the magnetic resonance imaging apparatus. In FIG. 8, the four receiving antennas 104 are disposed in one row. However, since the number of receiving antennas 104 which can be disposed within the housing 111 is changed by a receiving frequency, the number of antennas illustrated is one example. As another example, ten receiving antennas 104 in one row arranged in ten rows, i.e., 100 receiving antennas 104 can be disposed at one support.

In this way, as the receiving antenna 104 is disposed within the support needed in the magnetic resonance imaging apparatus of the vertical magnetic field type, the receiving antenna 104 can be disposed within the housing without narrowing or hardly narrowing the opening area or the imaging area. The present embodiment can be employed by the magnetic resonance imaging apparatus using an eternal magnet.

### Fourth Embodiment

A magnetic resonance imaging apparatus of a fourth embodiment is a form where the cooling by liquid nitrogen of the second embodiment is employed by the magnetic resonance imaging apparatus of the third embodiment. FIG. 9 illustrates a conceptual diagram of the magnetic resonance imaging apparatus of the fourth embodiment. The magnetic resonance imaging apparatus in FIG. 9 has a static magnetic field source 101, a gradient magnetic field coil 102, a transmission coil 103, a receiving antenna 104, a receiving unit 107, a housing 111, a cold head 209, and a second refrigerant chamber 300 containing a cooling refrigerant, such as liquid nitrogen. In the present embodiment, a magnet using a superconducting coil is used for the static magnetic field source 101. At least a part or a whole of a vacuum container accommodating a first refrigerant container accommodating the superconducting coil is covered with the second refrigerant chamber 300 accommodating a superconducting antenna. In the fourth embodiment, description of things in common with the aforementioned embodiments is omitted. Effects of the present configuration are as described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising: a housing; a static magnetic field source having a superconducting coil or a permanent magnet inside the housing; and a superconducting array antenna inside the housing.

2. The apparatus according to claim 1, wherein the static magnetic field source is a static magnetic field source having the superconducting coil, and
the superconducting array antenna is disposed on a circumference inside the superconducting coil.

3. The apparatus according to claim 1, wherein the static magnetic field source is a static magnetic field source having the superconducting coil, and
a plurality of the superconducting array antenna is disposed on a circumference inside the superconducting coil at equal intervals.

4. The apparatus according to claim 1, wherein the static magnetic field source is a static magnetic field source having the superconducting coil, and
a plurality of the superconducting array antenna is disposed so as to be surrounded by the static magnetic field source.

5. The apparatus according to claim 1, wherein the static magnetic field source is a static magnetic field source having the superconducting coil, and
the superconducting array antenna has directivity in a direction of a center part of the housing.

6. The apparatus according to claim 1, wherein the superconducting array antenna has one row or more.

7. The apparatus according to claim 1, wherein the superconducting coil and the superconducting array antenna are cooled by a common cooling medium.

8. The apparatus according to claim 1, wherein the superconducting array antenna has a superconducting filter and a low noise amplifier.

9. The apparatus according to claim 1, wherein the superconducting array antenna is a phased array antenna, and
the superconducting array antenna is connected with a phase shifter.

10. The apparatus according to claim 1, wherein the superconducting coil and the superconducting array antenna are cooled in a superconducting state.

11. The apparatus according to claim 1, further comprising:
a refrigerant container configured to contain a cooling refrigerant including liquid helium or liquid nitrogen,
wherein the superconducting array antenna is accommodated within the refrigerant container.

12. The apparatus according to claim 11, wherein the static magnetic field source has a vacuum chamber, a refrigerant chamber containing a cooling refrigerant within the vacuum chamber, and the superconducting coil within the refrigerant chamber, and
at least a part of the vacuum chamber is covered with a refrigerant container accommodating the superconducting array antenna.
